(19) United States
(12) Patent Application Publication
(10) Pub. No.: US 2008/0237738 A1
(43) Pub. Date: Oct. 2, 2008

(54) Integrated circuit, cell, cell arrangement, method for manufacturing an integrated circuit, method for manufacturing a cell arrangement; memory module

(76) Inventors: Christoph Andreas Kleint, Dresden (DE); Dirk Manger, Dresden (DE); Nicolas Nagel, Dresden (DE); Andreas Taeuber, Unterschleissheim (DE)

Correspondence Address: SLATER & MATSIL, L.L.P., 17950 PRESTON ROAD, SUITE 1000, DALLAS, TX, 75252, US

(21) Appl. No.: 11/728,970

(22) Filed: Mar. 27, 2007

(51) Int. Cl. H01L 29/78; H01L 21/336

(52) U.S. Cl. 257/383; 257/384; 438/197; 257/E21.409; 257/E29.255

(57) ABSTRACT

The present invention relates generally to integrated circuits, a cell, a cell arrangement, a method for manufacturing an integrated circuit, a method for manufacturing a cell arrangement and a memory module. In an embodiment of the invention, an integrated circuit having a cell is provided. The cell includes a first source/drain region, a second source/drain region, an active region between the first source/drain region and the second source/drain region, a gate insulating region disposed above the active region, a gate region disposed above the gate insulating region, and at least one metal structure below the first source/drain region or the second source/drain region.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of embodiments of the invention. In the following description, various embodiments of the invention are described with reference to the following drawings, in which:

FIG. 1 shows a cross sectional view of a conventional memory cell arrangement;

FIG. 2 shows a cell in accordance with an embodiment of the invention;

FIG. 3 shows a cell in accordance with another embodiment of the invention;

FIG. 4 shows a cell in accordance with yet another embodiment of the invention;

FIG. 5 shows a cell in accordance with yet another embodiment of the invention;

FIG. 6 shows a cell in accordance with yet another embodiment of the invention;

FIG. 7 shows a flow diagram illustrating a method for manufacturing a cell in accordance with an embodiment of the invention;

FIG. 8 shows a cell arrangement in accordance with an embodiment of the invention;

FIG. 9 shows a flow diagram illustrating a method for manufacturing a cell arrangement in accordance with an embodiment of the invention;

FIG. 10 shows a cross sectional view of a memory cell arrangement at a first stage of its manufacture in accordance with an embodiment of the invention;

FIG. 11 shows a cross sectional view of a memory cell arrangement at a second stage of its manufacture in accordance with an embodiment of the invention;

FIG. 12 shows a cross sectional view of a memory cell arrangement at a third stage of its manufacture in accordance with an embodiment of the invention;

FIG. 13 shows a cross sectional view of a memory cell arrangement at a fourth stage of its manufacture in accordance with an embodiment of the invention;

FIG. 14 shows a cross sectional view of a memory cell arrangement at a fifth stage of its manufacture in accordance with an embodiment of the invention; and

FIGS. 15A and 15B show a memory module (FIG. 15A) and a stackable memory module (FIG. 15B) in accordance with an embodiment of the invention.

### DETAILED DESCRIPTION OF ILLUSTRATIVE EMBODIMENTS

Embodiments of the invention relate generally to an integrated circuit, a cell, a cell arrangement, a method for manufacturing an integrated circuit, a method for manufacturing a cell arrangement and a memory module.

In a conventional charge trapping memory cell arrangement, so called buried bit lines may be used. The buried bit lines are formed by implantation of the source/drain regions of the respective charge trapping memory cells of the charge trapping memory cell arrangement.

In this case, the resistance of the source/drain region and the resistance of the respective buried bit line are coupled. If the charge trapping memory cell arrangement is scaled down, shallow junctions may become necessary which may result in a high electrical resistance of the bit lines.

In a conventional charge trapping memory cell arrangement such as, e.g., in an NROM (Nitrided Read Only Memory) memory cell arrangement, e.g., in a Twin Flash memory cell arrangement using a 170 nm process technology, so called buried bit lines are used. The conventional buried bit lines are formed by implantation of the source/drain regions of the charge trapping memory cells.

In this case, the resistance of the source/drain regions and the buried bit line resistance of the respectively coupled buried bit line are coupled. If the charge trapping memory cells are scaled down, shallow junctions may become necessary which may result in a too high bit line resistance.

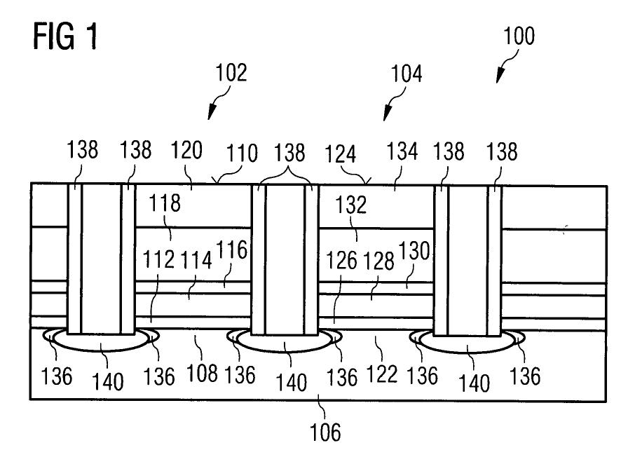

FIG. 1 shows a cross sectional view of a conventional memory cell arrangement 100 including a first charge trapping memory cell 102 and a second charge trapping memory cell 104 being arranged next to the first charge trapping memory cell 102.

The memory cell arrangement 100 has a carrier 106, e.g., a substrate 106.

The first charge trapping memory cell 102 includes an active region 108. The active region 108 may be rendered electrically conductive (in other words form a conductive channel) in response to an appropriate voltage application to a gate region and to a first source/drain region and a second source/drain region, which will be described in more detail below. Furthermore, the first charge trapping memory cell 102 includes a gate stack 110 arranged on or above the active region 108. The gate stack 110 includes a gate insulating layer 112, e.g., made of an oxide, e.g., made of silicon oxide (SiO₂), being arranged on or above the active region 108. Furthermore, the gate stack 110 includes a charge trapping region being arranged on or above the gate insulating layer 112. In case that the first charge trapping memory cell 102 is an Oxide-Nitride-Oxide (ONO) type charge trapping memory cell, the charge trapping region includes a charge trapping layer 114, e.g., made of a nitride, e.g., made of silicon nitride, being arranged on or above the gate insulating layer 112 and a top oxide layer 116, e.g., made of silicon oxide (SiO₂) or aluminum oxide (Al₂O₃) being arranged on or above the charge trapping layer 114. The gate stack 110 further includes a gate region 118, e.g., made of poly-silicon or any other suitable gate material. The gate region 118 may include one or a plurality of layers, e.g., a layer stack of two or more layers. In one embodiment, the gate region 118 includes two layers, e.g., a layer stack comprising a poly-silicon layer and a tungsten salicide layer on or above the poly-silicon layer. In another embodiment, the layer stack comprises a poly-silicon layer and a tungsten layer on or above the poly-silicon layer. Furthermore, a further nitride layer 120, e.g., made of silicon nitride, is provided on or above the gate region 118.

The second charge trapping memory cell 104 includes an active region 122. The active region 122 may be rendered electrically conductive (in other words form a conductive channel) in response to an appropriate voltage application to a gate region and to a first source/drain region and a second source/drain region, which will be described in more detail below. Furthermore, the second charge trapping memory cell 104 includes a gate stack 124 arranged on or above the active region 122. The gate stack 124 includes a gate insulating layer 126, e.g., made of an oxide, e.g., made of silicon oxide (SiO₂), being arranged on or above the active region 122. Furthermore, the gate stack 124 includes a charge trapping region being arranged on or above the gate insulating layer 126. In case that the second charge trapping memory cell 104 is an Oxide-Nitride-Oxide (ONO) type charge trapping memory cell, the charge trapping region includes a charge trapping layer 128, e.g., made of a nitride, e.g., made of silicon nitride, being arranged on or above the gate insulating layer 126 and a top oxide layer 130, e.g., made of silicon oxide (SiO₂) or aluminum oxide (Al₂O₃) being arranged on or above the charge trapping layer 128. The gate stack 124 further includes a gate region 132, e.g., made of poly-silicon or any other suitable gate material. The gate region 132 may include one or a plurality of layers, e.g., a layer stack of two or more layers. In one embodiment, the gate region 132 includes two layers, e.g., a layer stack comprising a poly-silicon layer and a tungsten salicide layer on or above the poly-silicon layer. In another embodiment, the layer stack comprises a poly-silicon layer and a tungsten layer on or above the poly-silicon layer. Furthermore, a further nitride layer 134, e.g., made of silicon nitride, is provided on or above the gate region 132.

The first charge trapping memory cell 102 and the second charge trapping memory cell 104 each comprise a first source/drain region and a second source/drain region. Conventionally, the source/drain regions of the respectively adjacent charge trapping memory cells are common source/drain regions. Furthermore, as shown in FIG. 1, a buried bit line is also formed together with the source/drain regions. In one embodiment, this structure is formed by patterning the gate stacks 110, 124 of the charge trapping memory cells 102, 104, thereby exposing the upper surface of a region of the substrate 106. Next, a pocket implantation is performed in the exposed regions of the substrate 106, thereby forming pocket implants 136. Then, spacers 138 are formed on the sidewalls of the trenches formed above the exposed upper surface of the substrate 106. The spacers 138 may be made of an oxide such as, e.g., silicon oxide. Then, a further implantation of the still exposed regions of the upper surface of the substrate 106 is performed, thereby forming the buried bit line 140 (which together with the pocket implants 136 also forms the source/drain regions of the charge trapping memory cells 102, 104). The series connection of all buried bit line portions along one line (which corresponds to the series connection of a plurality of charge trapping memory cells, which may be coupled, e.g., in accordance with a NAND structure) together form one buried bit line. In other words, the junctions formed in the above described manner act as source/drain regions for the respective charge trapping memory cells and as the buried bit line.

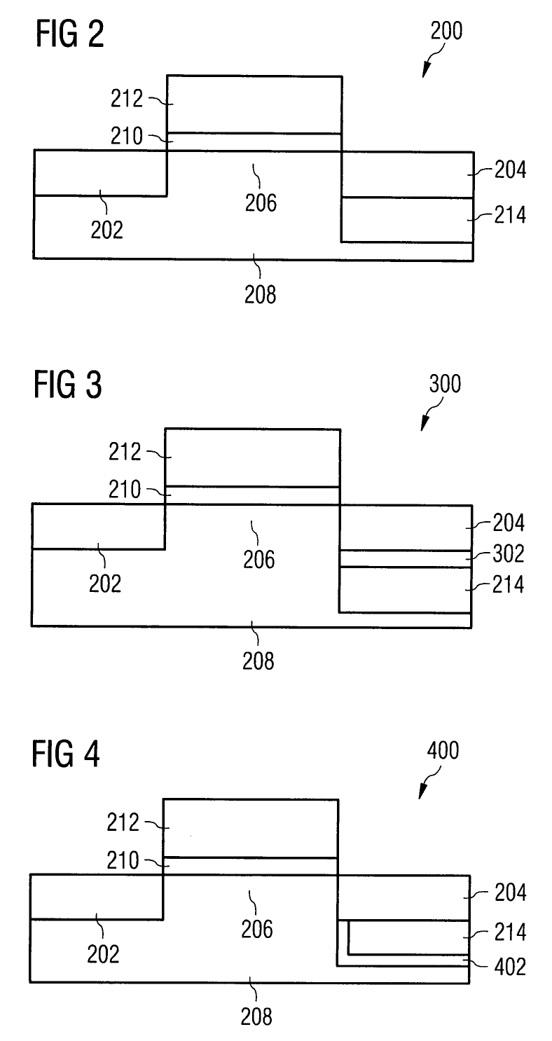

FIG. 2 shows a cell 200 in accordance with an embodiment of the invention.

It should be mentioned that in one embodiment of the invention, the described cells as well as the described cell arrangements may be monolithically integrated in one integrated circuit or in a plurality of integrated circuits.

In one embodiment of the invention, the cell 200 is a transistor-type cell. The cell 200 may include a first source/drain region 202 and a second source/drain region 204.

It should be mentioned that in different embodiments of the invention, the cells could be transistor-type (e.g., field effect transistor-type) logic cells and/or transistor-type (e.g., field effect transistor-type) memory cells.

Furthermore, the cell 200 may include an active region 206 in a carrier 208, e.g., a substrate 208. In one embodiment of the invention, the substrate 208 is made of semiconductor material, although in another embodiment of the invention, other suitable materials can also be used, e.g., polymers. In an exemplary embodiment of the invention, the substrate 208 is made of silicon (doped or undoped), in an alternative embodiment of the invention, the substrate 208 is a silicon on insulator (SOI) wafer. As an alternative, any other suitable semiconductor materials can be used for the substrate 208, for example, semiconductor compound material such as gallium arsenide (GaAs), indium phosphide (InP), but also any suitable ternary semiconductor compound material or quaternary semiconductor compound material such as, e.g., indium gallium arsenide (InGaAs).

In one embodiment of the invention, the cell 200 further includes a gate insulating region 210, e.g., a gate insulating layer 210, disposed above the active region 206. Furthermore, a gate region 212, e.g., a gate layer 212, is disposed above the gate insulating region 210.

The active region 206 may be rendered electrically conductive (in other words form a conductive channel) in response to an appropriate voltage application to the gate region 212 and to the first source/drain region 202 and the second source/drain region 204.

As shown in FIG. 2, at least one metal structure 214 is provided below the second source/drain region 204. In an alternative embodiment of the invention, the at least one metal structure 214 is provided below the first source/drain region 202. In yet an alternative embodiment of the invention, at least one metal structure 214 is provided below the first source/drain region 202 and below the second source/drain region 204. In other words, e.g., depending on the cell arrangement architecture, e.g., depending on the cell array architecture, the at least one metal structure 214 may be provided below each source/drain region 202, 204 or only to some of the source/drain regions of adjacent cells 200, e.g., below every second (in alternative embodiments below every third, fourth, etc.) source/drain regions along a series connection of cells 200.

In one embodiment of the invention, the first source/drain region 202 and the second source/drain region 204 are n-doped regions (in case that the cell 200 is an n-type transistor) or p-doped regions (in case that the cell 200 is a p-type transistor).

In one embodiment of the invention, the at least one metal structure 214 is made of a material that acts as a diffusion barrier with regard to the material of the carrier 208 and/or of a material that acts as a diffusion barrier with regard to the material of the second source/drain region 204, in general with regard to the material of the source drain/region that is disposed above the at least one metal structure 214.

In other words, in one embodiment of the invention, the at least one metal structure 214 is made of a material that acts as a diffusion barrier with regard to the material of the carrier 208.

In case that the material of the at least one metal structure 214 does not act as a diffusion barrier with regard to the material of the source/drain region that is disposed above the at least one metal structure 214, an additional diffusion barrier layer is provided between the at least one metal structure 214 and the respective source/drain region.

In case that the material of the at least one metal structure 214 does act as a diffusion barrier with regard to the material of the source/drain region that is disposed above the at least one metal structure 214, no additional diffusion barrier layer is necessary and the respective source/drain region may be formed directly on or above the at least one metal structure 214.

In another embodiment of the invention, the at least one metal structure 214 is made of a material that acts as a diffusion barrier only with regard to the material of the source/drain region (e.g., the second source/drain region 204) that is disposed above the at least one metal structure 214, but not with regard to the material of the carrier 208. In this case, an additional diffusion barrier layer is provided between the material of the carrier 208 and the at least one metal structure 214, but no diffusion barrier layer is necessary between the respective source/drain region (e.g., the second source/drain region 204) that is disposed above the at least one metal structure 214 and the at least one metal structure 214, as will be described in more detail below.

In one embodiment of the invention, the at least one metal structure 214 illustratively acts as a bit line.

In one embodiment of the invention, the at least one metal structure 214 may be electrically coupled to the respective source/drain region.

In an embodiment, in which an additional diffusion barrier is provided between the at least one metal structure 214 and the respective source/drain region, the material of the additional diffusion barrier may be electrically conductive (e.g., the additional diffusion barrier may be made of tantalum nitride (TaN), thereby providing an electrical coupling between the source/drain region and the at least one metal structure 214.

In one embodiment of the invention, the carrier 208 is made of silicon. In this case, the at least one metal structure 214 is made of a material that acts as a diffusion barrier with regard to silicon. Examples of such a material are titanium nitride (TiN), titanium aluminum nitride (TiAlN), tantalum silicon nitride (TaSiN), a salicide such as, e.g., tungsten salicide (WSi), cobalt salicide (CoSi), titanium salicide (TiSi), tungsten nitride (WN), hafnium nitride (HfN), zirconium nitride (ZrN), tantalum nitride (TaN), etc.

In an embodiment of the invention, in which the at least one metal structure 214 is made of a material that does not act as a diffusion barrier with regard to the material of the carrier 208 (e.g., silicon), an additional diffusion barrier layer (in the case that silicon is used for the carrier, e.g., made of silicon oxide) may be provided between the carrier 208 and the at least one metal structure 214.

FIG. 3 shows a cell 300 in accordance with an embodiment of the invention, in which an additional diffusion barrier layer 302 (in case that silicon (e.g., doped or undoped amorphous silicon or doped or undoped poly-silicon) or carbon is used as the base material of the source/drain region 204) is provided between the at least one metal structure 214 and the respective source/drain region (e.g., the second source/drain region 204). In one embodiment of the invention, the additional diffusion barrier layer 302 is made of tantalum nitride (TaN), although any other suitable diffusion barrier material may be used in an alternative embodiment.

FIG. 4 shows a cell 400 in accordance with an embodiment of the invention, in which an additional diffusion barrier layer 402 (in case that silicon is used as the carrier 208, e.g., made of silicon oxide) is provided between the at least one metal structure 214 and the carrier 208. Although in one embodiment of the invention, the additional diffusion barrier layer 402 is made of silicon oxide, any other suitable diffusion barrier material may be used in an alternative embodiment.

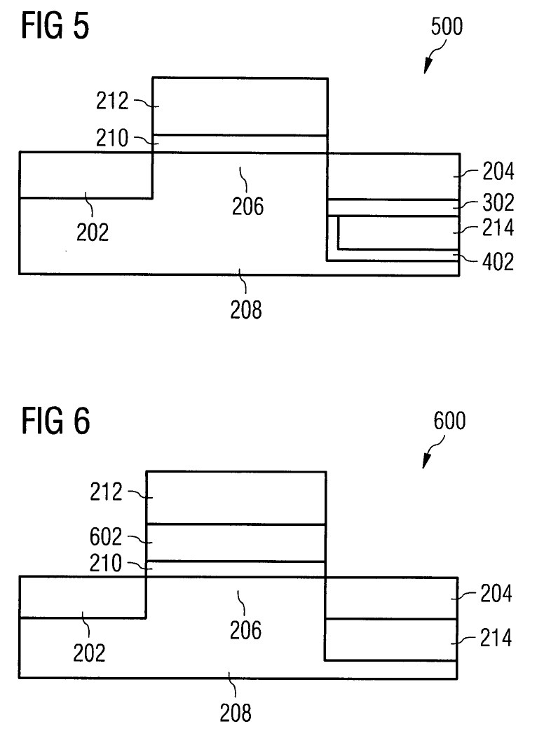

FIG. 5 shows a cell 500 in accordance with an embodiment of the invention, in which both additional diffusion barrier layers (the additional diffusion barrier layer 302 between the at least one metal structure 214 and the respective source/drain region (e.g., the second source/drain region 204) according to the cell 300 shown in FIG. 3 and the additional diffusion barrier layer 402 between the at least one metal structure 214 and the carrier 208 according to the cell 400 shown in FIG. 4) are provided.

FIG. 6 shows a memory cell 600 in accordance with yet another embodiment of the invention.

The memory cell 600 is similar to the cell 200 shown in FIG. 2 and further includes a charge storage region 602 between the gate insulating region 210 and the gate region 212.

In one embodiment of the invention, the memory cell 600 is a volatile memory cell.

In one embodiment of the invention, the memory cell 600 is a non-volatile memory cell.

In the context of this description, a “volatile memory cell” may be understood as a memory cell storing data, the data being refreshed during a power supply voltage of the memory system being active, in other words, in a state of the memory system, in which it is provided with power supply voltage. In contrast thereto, a “non-volatile memory cell” may be understood as a memory cell storing data, wherein the stored data is/are not refreshed during the power supply voltage of the memory system being active.

However, a “non-volatile memory cell” in the context of this description includes a memory cell, the stored data of which may be refreshed after an interruption of the external power supply. As an example, the stored data may be refreshed during a boot process of the memory system after the memory system had been switched off or had been transferred to an energy deactivation mode for saving energy, in which mode at least some or most of the memory system components are deactivated. Furthermore, the stored data may be refreshed on a regular timely basis, but not, as with a “volatile memory cell” every few picoseconds or nanoseconds or milliseconds, but rather in a range of hours, days, weeks or months.

In one embodiment of the invention, the memory cell 600 is a charge storage memory cell, e.g., a floating gate memory cell or a charge trapping memory cell.

In the embodiment, in which the memory cell 600 is a floating gate memory cell, the gate insulating region 210 may be a tunnel oxide layer and the charge storage region 602 may include a floating gate region (which may be formed from electrically conductive material such as, e.g., poly-silicon (doped or undoped)) formed on or above the gate insulating region 210 and a gate oxide layer (which may, e.g., be made of silicon oxide or aluminum oxide) formed on or above the floating gate region.

In the embodiment, in which the memory cell 600 is a charge trapping memory cell, a charge trapping layer structure may be provided. The charge trapping layer structure may include a dielectric layer stack including at least two dielectric layers being formed above one another (one dielectric layer of the two dielectric layers may be formed by the gate insulating layer 210 and the other dielectric layer of the two dielectric layers may be included in the charge storage region 602), wherein charge carriers can be trapped in at least one of the at least two dielectric layers. By way of example, the charge trapping layer structure includes a charge trapping layer, which may include or consist of one or more materials being selected from a group of materials that consists of: aluminium oxide (Al₂O₃), yttrium oxide (Y₂O₃), hafnium oxide (HfO₂), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminium, zirconium and oxygen (AlZrO). In one embodiment of the invention, the charge trapping layer structure includes a dielectric layer stack including three dielectric layers being formed above one another, e.g., a first oxide layer (e.g., silicon oxide) (e.g., formed by the gate insulating region 210), a nitride layer as charge trapping layer (e.g., silicon nitride) on the first oxide layer, and a second oxide layer (e.g., silicon oxide or aluminium oxide) on the nitride layer. This type of dielectric layer stack is also referred to as ONO layer stack. In an alternative embodiment of the invention, the charge trapping layer structure includes two, four or even more dielectric layers being formed above one another.

The memory cell structures described with reference to FIG. 6 can in other embodiments of the invention also be applied to the embodiments shown in the FIGS. 3 to 5 and to the embodiments that will be described below.

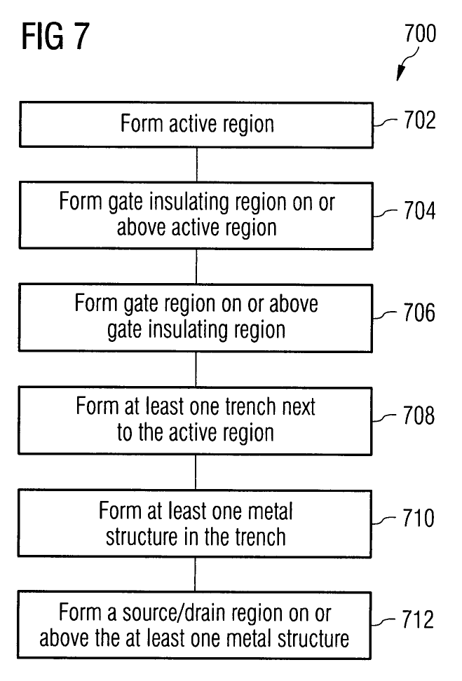

FIG. 7 shows a flow diagram 700 illustrating a method for manufacturing a cell in accordance with an embodiment of the invention (in one embodiment of the invention for manufacturing an integrated circuit having a cell).

At 702, an active region is formed, e.g., in a carrier such as, e.g., in a substrate 208 (e.g., made of a semiconductor material such as, e.g., silicon).

At 704, a gate insulating region (e.g., a gate insulating layer, e.g., made of silicon oxide) is formed (e.g., deposited using, e.g., a chemical vapour deposition process (CVD) or a physical vapour deposition process (PVD)) on or above the active region.

At 706, a gate region (e.g., including forming one or a plurality of layers including electrically conductive material such as, e.g., poly-silicon) is formed (e.g., deposited using, e.g., a chemical vapour deposition process (CVD) or a physical vapour deposition process (PVD)) on or above the gate insulating region.

At 708, at least one trench is formed (e.g., etched, e.g., anisotropically etched, e.g., using wet etching or dry etching, e.g., using reactive ion etching (RIE)) next to the active region (in one embodiment of the invention respectively between two gate stacks to be formed in the area, in which the source/drain regions should be formed). In one embodiment of the invention, the trench extends into the carrier 208 deeper than the depth of the source/drain regions to be formed. In one embodiment of the invention, the trench extends up to a depth into the carrier 208 (considered from the upper surface of the carrier 208) in the range of about 20 nm to about 150 nm, e.g., in the range of about 40 nm to about 100 nm, e.g., about 50 nm. In one particular embodiment of the invention, the forming of the at least one trench next to the active region includes forming a first trench on one side next to the active region and forming a second trench on the opposite side of the active region next to the active region. In other words, in accordance with this particular embodiment of the invention, two trenches are formed next to each cell, namely a first trench provided for the first source/drain region to be manufactured on the one side of the cell and a second trench provided for the second source/drain region to be manufactured on the other side of the cell, thereby, e.g., providing a transistor-type cell.

At 710, at least one metal structure is formed in the at least one trench (e.g., deposited using, e.g., a chemical vapour deposition process (CVD) or a physical vapour deposition process (PVD)) on or above the exposed carrier 208. In one embodiment of the invention, the at least one metal structure is deposited having a metal structure thickness in the range of about 5 nm to about 100 nm, e.g., in the range of about 20 nm to about 50 nm, e.g., about 30 nm. In one particular embodiment of the invention, the forming of the at least one metal structure in the trench includes forming a first metal structure in the first trench and forming a second metal structure in the second trench.

Then, at 712, a source/drain region is formed (e.g., deposited using, e.g., a chemical vapour deposition process (CVD) or a physical vapour deposition process (PVD)) on or above the at least one metal structure. In one particular embodiment of the invention, the forming the source/drain region above the at least one metal structure includes forming a first source/drain region on or above the first metal structure and forming a second source/drain region on or above the second metal structure.

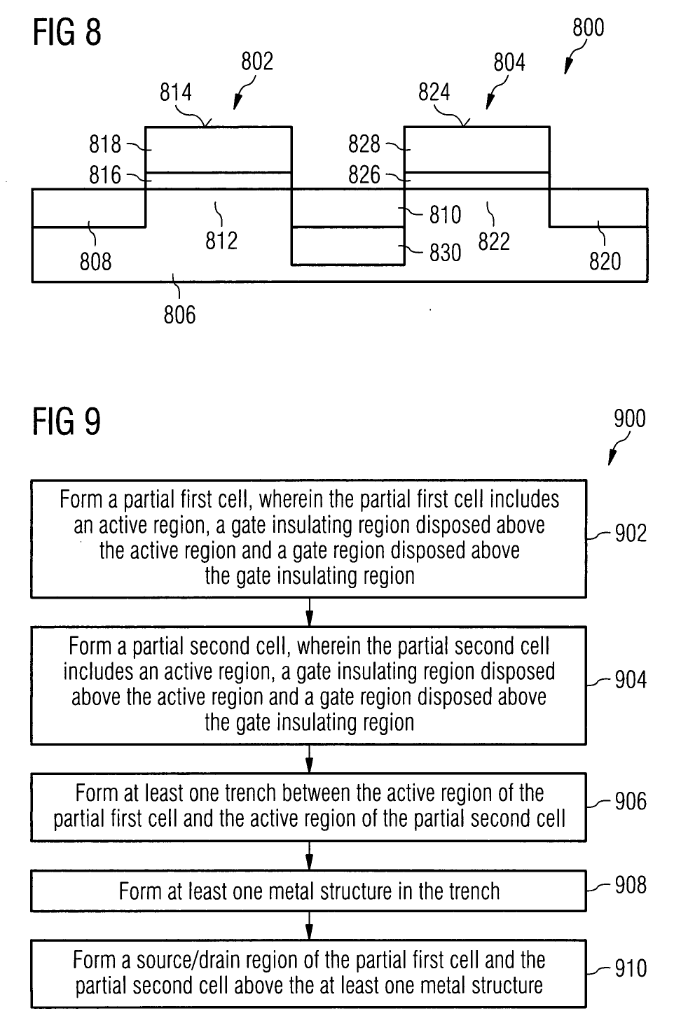

FIG. 8 shows a cell arrangement 800 in accordance with an embodiment of the invention.

In one embodiment of the invention, the cell arrangement 800 includes a first cell 802 and a second cell 804. The first cell 802 and the second cell 804 may be any of the cells described above with regard to the various embodiments.

The cells 802, 804 are manufactured in or above a carrier 806 as the cells described above.

The first cell 802 includes a first source/drain region 808 and a second source/drain region 810 and an active region 812 in the carrier 806 between the first source/drain region 808 and the second source/drain region 810. The active region 812 may be rendered electrically conductive (in other words form a conductive channel) in response to an appropriate voltage application to a gate region and to the first source/drain region 808 and the second source/drain region 810, which will be described in more detail below. Furthermore, the first cell 802 includes a gate stack 814 arranged on or above the active region 812. The gate stack 814 includes a gate insulating layer 816, e.g., made of an oxide, e.g., made of silicon oxide (SiO₂), being arranged on or above the active region 812. Furthermore, the gate stack 814 includes a gate region 818, e.g., made of poly-silicon or any other suitable gate material. The gate region 818 may include one or a plurality of layers, e.g., a layer stack of two or more layers. In one embodiment, the gate region 818 includes two layers, e.g., a layer stack comprising a poly-silicon layer and a tungsten salicide layer on or above the poly-silicon layer. In another embodiment, the layer stack comprises a poly-silicon layer and a tungsten layer on or above the poly-silicon layer.

The second cell 804 includes a first source/drain region 810 (which in one particular embodiment of the invention is a common (shared) source/drain region with the second source/drain region 810 of the first cell 802), a second source/drain region 820 and an active region 822 in the carrier 806 between the first source/drain region 810 and the second source/drain region 820. The active region 822 may be rendered electrically conductive (in other words form a conductive channel) in response to an appropriate voltage application to a gate region and to the first source/drain region 810 and the second source/drain region 820, which will be described in more detail below. Furthermore, the second cell 804 includes a gate stack 824 arranged on or above the active region 822. The gate stack 824 includes a gate insulating layer 826, e.g., made of an oxide, e.g., made of silicon oxide (SiO₂), being arranged on or above the active region 822. Furthermore, the gate stack 824 includes a gate region 828, e.g., made of poly-silicon or any other suitable gate material. The gate region 828 may include one or a plurality of layers, e.g., a layer stack of two or more layers. In one embodiment, the gate region 828 includes two layers, e.g., a layer stack comprising a poly-silicon layer and a tungsten salicide layer on or above the poly-silicon layer. In another embodiment, the layer stack comprises a poly-silicon layer and a tungsten layer on or above the poly-silicon layer.

In one embodiment of the invention, at least one metal structure 830 is provided below the second source/drain region 810 of the first cell 802 and the first source/drain region 810 of the second cell 804 (in one embodiment of the invention below the common source/drain region shared by the first cell 802 and the second cell 804).

All embodiments described with reference to the cells also refer analogously to the various embodiments of the cell arrangement.

FIG. 9 shows a flow diagram 900 illustrating a method for manufacturing a cell arrangement in accordance with an embodiment of the invention.

At 902, a partial first cell is formed, wherein the partial first cell includes an active region, a gate insulating region disposed above the active region, and a gate region disposed above the gate insulating region.

At 904, a partial second cell is formed, wherein the partial second cell includes an active region, a gate insulating region disposed above the active region, and a gate region disposed above the gate insulating region.

At 906, at least one trench (e.g., etched, e.g., anisotropically etched, e.g., using wet etching or dry etching) is formed between the active region of the partial first cell and the active region of the partial second cell (in one embodiment of the invention respectively between the two gate stacks to be formed in the area, in which the source/drain regions should be formed). In one embodiment of the invention, the trench extends into the carrier 806 deeper than the depth of the source/drain regions to be formed. In one embodiment of the invention, the trench extends up to a depth into the carrier 806 (considered from the upper surface of the carrier 806) in the range of about 20 nm to about 150 nm, e.g., in the range of about 40 nm to about 100 nm, e.g., about 50 mm.

At 908, at least one metal structure is formed in the trench (e.g., deposited using, e.g., a chemical vapour deposition process (CVD) or a physical vapour deposition process (PVD)) on or above the exposed carrier 806. In one embodiment of the invention, the at least one metal structure is deposited having a metal structure thickness in the range of about 5 nm to about 100 nm, e.g., in the range of about 20 nm to about 50 nm, e.g., about 30 nm.

At 910, a source/drain region of the partial first cell and the partial second cell is formed (e.g., deposited using, e.g., a chemical vapour deposition process (CVD) or a physical vapour deposition process (PVD)) on or above the at least one metal structure.

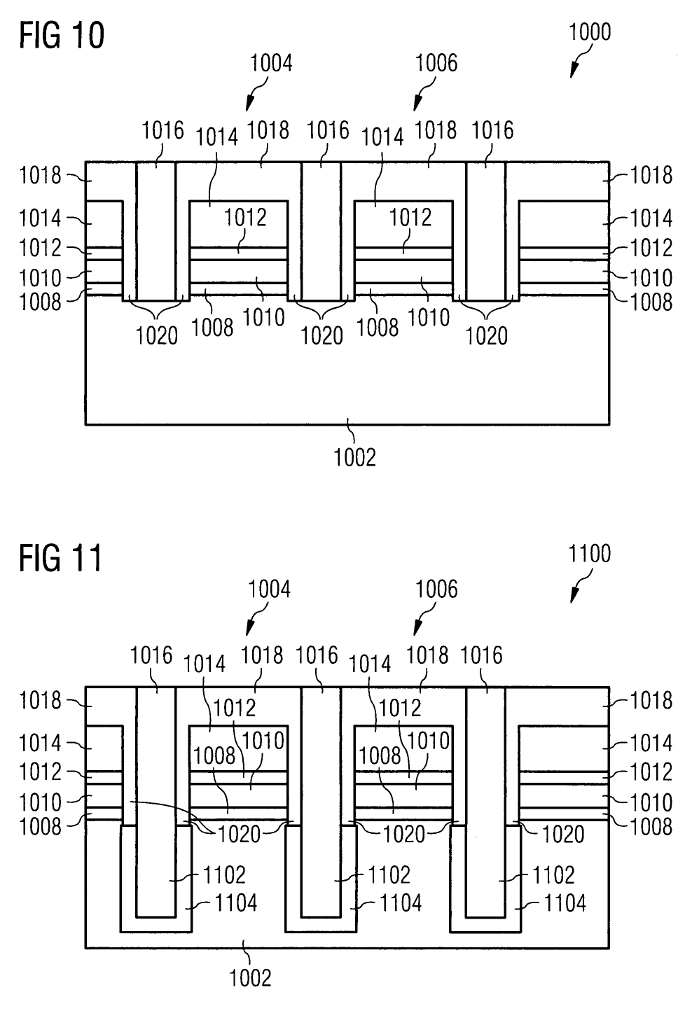

FIG. 10 shows a cross sectional view of a memory cell arrangement 1000 at a first stage of its manufacture in accordance with an embodiment of the invention.

The memory cell arrangement 1000 includes a carrier 1002, e.g., a substrate 1002 such as, e.g., a substrate 1002 made of a material as described above (e.g., a silicon substrate).

As illustrated in FIG. 10, a first memory cell 1004 and a second memory cell 1006 to be formed are shown at a first stage of its manufacture. Although only two memory cells are shown in the figures, any number of memory cells (e.g., hundreds, thousands or millions) may be provided in the memory cell arrangement 1000 in accordance with an embodiment of the invention. Furthermore, the memory cells can be of any type that has been described above, for example. In one embodiment of the invention, the memory cells 1004, 1006 are charge trapping memory cells 1004, 1006, e.g., ONO memory cells 1004, 1006.

In one embodiment of the invention, to form the memory cell arrangement 1000 shown in FIG. 10, a first oxide layer 1008 (also referred to as bottom oxide layer), which may be made of silicon oxide, is formed (e.g., deposited using a CVD process or a PVD process) on or above the upper surface of the carrier 1002. The first oxide layer 1008 may be formed having a thickness in the range of about 3 nm to about 5 nm.

In an alternative embodiment of the invention, in which the memory cells 1004, 1006 are floating gate memory cells 1004, 1006, the also in this case formed first oxide layer 1008 (also referred to as tunnel dielectric in this case) may be formed having a thickness in the range of about 3 nm to about 15 nm.

Then, in the embodiment, in which the memory cells 1004, 1006 are charge trapping memory cells 1004, 1006, a charge trapping layer 1010 (e.g., made of a material as described above) is formed (e.g., deposited using a CVD process or a PVD process) on or above first oxide layer 1008. Next, a second oxide layer 1012 (e.g., made of silicon oxide or aluminum oxide) is formed (e.g., deposited using a CVD process or a PVD process) on or above the charge trapping layer 1010. The first oxide layer 1008, the charge trapping layer 1010 and the second oxide layer 1012 form the so called ONO layer stack.

In the alternative embodiment of the invention, in which the memory cells 1004, 1006 are floating gate memory cells 1004, 1006, a floating gate layer (e.g., made of poly-silicon) is formed (e.g., deposited using a CVD process or a PVD process) on or above the first oxide layer 1008 and a second oxide layer (also referred to as gate dielectric) is formed (e.g., deposited using a CVD process or a PVD process) on or above the floating gate layer.

Then, in both embodiments, a gate layer 1014 (e.g., made of electrically conductive material such as, e.g., poly-silicon) is formed (e.g., deposited using a CVD process or a PVD process) on or above the second oxide layer 1012. Next, the thus formed layer stack is patterned (e.g., using anisotropic etching, e.g., anisotropic wet etching or anisotropic dry etching, e.g., using reactive ion etching (RIE)), thereby forming first trenches 1016 extending through the entire layer stack into the carrier 1002, wherein the first trenches 1016 extend into the carrier 1002 (considered from the upper surface of the carrier 1002) by a depth in the range of about 10 nm to about 100 mm.

Next, a nitride layer 1018 (e.g., made of silicon nitride) is formed on the resulting structure, i.e. on or above the upper surface of the remaining second oxide layer 1012, on or above the sidewalls of the first trenches 1016 and on or above the exposed regions of the carrier 1002.

Then, nitride spacers 1020 are formed by anisotropic etching (e.g., anisotropic wet etching or anisotropic dry etching, e.g., reactive ion etching (RIE)) the nitride layer 1018, thereby again exposing some regions of the carrier 1002 at the bottom of the first trenches 1016.

FIG. 11 shows a cross sectional view of a memory cell arrangement 1100 at a second stage of its manufacture in accordance with an embodiment of the invention.

As shown in FIG. 11, second trenches 1102 are formed by further etching the exposed regions of the carrier within the first trenches 1016 using the nitride spacers 1020 as etching mask. The second trenches 1102 extend into the carrier 1002 (considered from the upper surface of the carrier 1002) by a depth in the range of about 20 nm to about 150 nm. Illustratively, the second trenches 1102 are further deepened first trenches 1016.

Then, the exposed material (e.g., silicon) of the carrier 1002 within the second trenches 1102 is oxidized (to, e.g., silicon oxide) e.g., by means of rapid thermal processing (RTP), thereby forming a U-shaped oxide layer 1104 (e.g., silixon oxide layer) on sidewalls of the lower portion (below the nitride spacers 1020) of the second trenches 1102 and the bottom of the second trenches 1102.

In an embodiment of the invention, an additional channel stop region is provided around the U-shaped oxide layer 1104 in the substrate 1002 in order to prevent a parasitic device with a parasitic channel region along the U-shaped oxide layer 1104. The additional channel stop region may be formed by means of an out-diffusion of doping atoms or by means of a suitable implantation process (e.g., with a concentration of doping atoms in the range of about 10¹⁸ cm⁻³ to about 5*10¹⁸ cm⁻³). In an embodiment of the invention, in which the devices to be formed are n-channel field effect transistors, boron ions (B or BF₂) may be used as doping atoms for forming the channel stop region. In an embodiment of the invention, in which the devices to be formed are p-channel field effect transistors, arsenic ions (As) or phosphorous ions (P) may be used as doping atoms for forming the channel stop region.

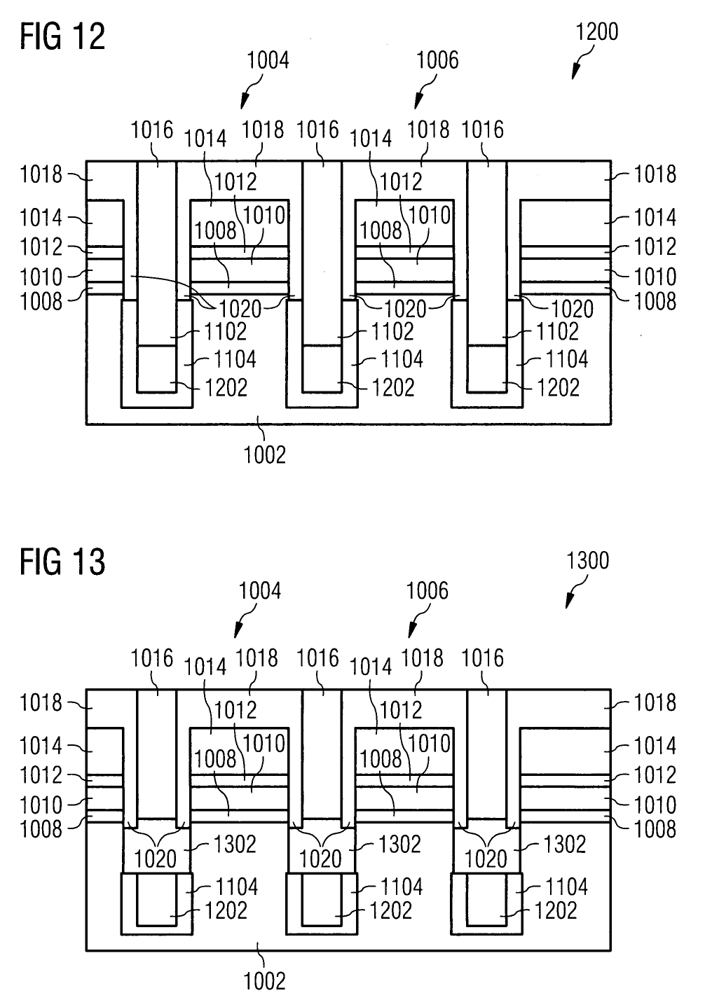

FIG. 12 shows a cross sectional view of a memory cell arrangement 1200 at a third stage of its manufacture in accordance with an embodiment of the invention.

As shown in FIG. 12, metal is then deposited on the structure 1100 shown in FIG. 12 and the metal deposition is recessed, thereby forming metal structures 1202 (which will form the bit lines) in the bottom part of the second trenches 1102.

In one embodiment of the invention, a metal is used for the metal structures 1202 that is a carrier diffusion barrier metal (e.g., a silicon diffusion barrier metal), in other words a metal that acts as a diffusion barrier with regard to the carrier material (e.g., a metal that acts as a diffusion barrier with regard to silicon). In one embodiment of the invention, the metal is a metal selected from a group of metals consisting of titanium nitride (TiN), titanium aluminum nitride (TiAlN), tantalum silicon nitride (TaSiN). In another embodiment of the invention, the metal is a salicide such as, e.g., tungsten salicide (WSi), cobalt salicide (CoSi) or titanium salicide (TiSi), tungsten nitride (WN), hafnium nitride (HfN), zirconium nitride (ZrN), tantalum nitride (TaN). In these embodiments, in which the metal itself is a carrier diffusion barrier metal (e.g., a silicon diffusion barrier metal), the U-shaped oxide layer 1104 (e.g., silixon oxide layer) on sidewalls of the lower portion (below the nitride spacers 1020) of the second trenches 1102 and the bottom of the second trenches 1102 might be omitted.

In an embodiment of the invention, in which a metal (e.g., tungsten (W)) is used for the metal structures 1202, which is not a diffusion barrier metal with regard to the material which is used for forming the source/drain regions (in one embodiment of the invention amorphous silicon for the material used for forming the source/drain regions) (e.g., not a silicon diffusion barrier metal), an additional diffusion barrier layer (e.g., made of tantalum nitride (TaN) is deposited (and recessed) on or above the upper surface of the metal structures 1202 (not shown).

In one embodiment of the invention, the metal structures 1202 have a thickness in the range of about 10 nm to about 50 nm.

As shown in FIG. 12, the upper surface of the metal structures 1202 is below the nitride spacers 1020 so that there are some exposed portions of the U-shaped oxide layer 1104 (e.g., silixon oxide layer).

FIG. 13 shows a cross sectional view of a memory cell arrangement 1300 at a fourth stage of its manufacture in accordance with an embodiment of the invention.

Next, as shown in FIG. 13, the exposed portions of the U-shaped oxide layer 1104 (e.g., silixon oxide layer) are removed (e.g., etched away, e.g., by means of wet etching), thereby exposing carrier material (e.g., silicon) within the second trenches 1102.

Furthermore, diffusion source material 1302 (e.g., a material, in which the source/drain regions may be formed later on) is deposited in the second trenches 1102 on or above the upper surface of the metal structures 1202 (or, if the metal structures 1202 are not a diffusion barrier with regard to the diffusion source material, on or above the upper surface of the additionally provided diffusion barrier layer), e.g., by means of a CVD process or a PVD process.

In one embodiment of the invention, the diffusion source material 1302 is formed having a thickness in the range of about 20 nm to about 50 nm.

In one embodiment of the invention, the diffusion source material 1302 is electrically conductive material.

In one embodiment of the invention, the diffusion source material 1302 is a material selected from a group of materials consisting of amorphous silicon, poly-silicon, carbon, germanium (e.g., pure germanium), salicide (e.g., cobalt salicide (CoSi)).

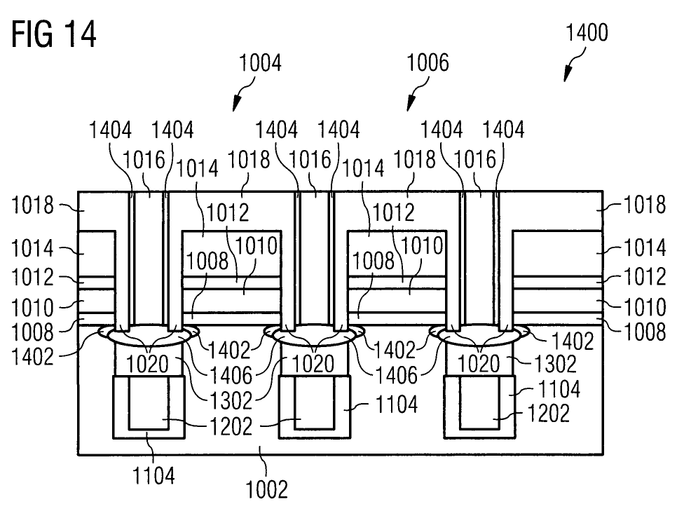

FIG. 14 shows a cross sectional view of a memory cell arrangement 1400 at a fifth stage of its manufacture in accordance with an embodiment of the invention.

As shown in FIG. 14, a pocket implantation is performed in the exposed regions of the diffusion source material 1302, thereby forming pocket implants 1402.

Then, spacers 1404 are formed on the exposed sidewalls of the second trenches 1102 formed on or above the exposed upper surface of the diffusion source material 1302. The spacers 1404 may be made of an oxide such as, e.g., silicon oxide. In one embodiment of the invention, the spacers 1404 may be formed by depositing (e.g., by means of a CVD process or by means of a PVD process) the spacer material (e.g., silicon oxide) and then carrying out a spacer etching (e.g., an anisotropic etching, e.g., using a reactive ion etching (RIE)).

Then, a further implantation of the still exposed regions of the upper surface of the diffusion source material 1302 is performed, thereby forming source/drain regions 1406 (together with the pocket implants 1402) of the charge trapping memory cells 1004, 1006 (or, in an alternative embodiment of the invention, of floating gate memory cells 1004, 1006).

As shown in FIG. 14, the resistance of the bit lines formed by the metal structures 1202 is decoupled from the resistance of the source/drain regions 1406, e.g., by the undoped region of the diffusion source material 1302 below the source/drain regions 1406.

Then, the conventional processes for completing the memory cell arrangement are executed, e.g., Back-End-Of-Line processes (BEOL) such as for wiring, packaging, etc.

In one embodiment of the invention, illustratively, a trench filled with metal under and connected with the source/drain area of the cell is formed.

In one embodiment of the invention, illustratively, a bit line is introduced in a trench. The trench may be filled with a metal and may be connected to the source/drain regions in the following way:

Forming a silicon diffusion barrier over the trench filled with metal; or the metal itself is a silicon diffusion barrier (like for example titanium nitride (TiN)).

Depositing amorphous poly-silicon over the diffusion barrier.

Implanting the source/drain region.

By doing this, the bit line resistance is decoupled from the optimum conditions for the source/drain regions (also referred to as source/drain junctions) to make a small cell. Because a metal is used in the trench, the bit line resistance is low. Secondaries formed by hot electrons will be captured by the metal in the trench, which will suppress the disturb of the next cell.

In one embodiment of the invention, illustratively, a trench is formed and partially filled with metal. Then a connection is made with a diffusion barrier to source/drain junctions from the charge trapping memory cell (or from the floating gate memory cell).

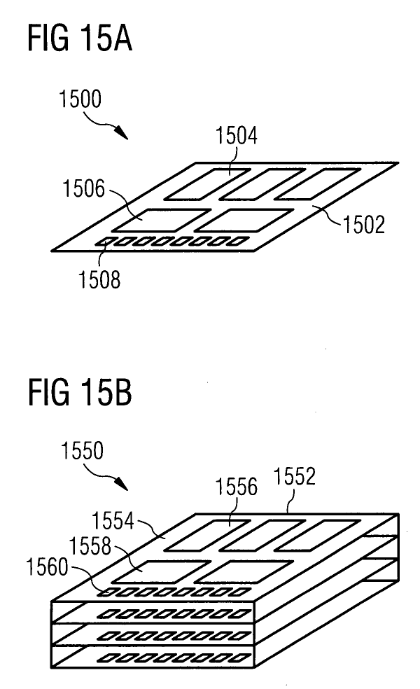

As shown in FIGS. 15A and 15B, in some embodiments, memory devices such as those described herein may be used in modules. In FIG. 15A, a memory module 1500 is shown, on which one or more memory devices 1504 are arranged on a substrate 1502. The memory device 1504 may include numerous memory cells, each of which uses a memory element in accordance with an embodiment of the invention. The memory module 1500 may also include one or more electronic devices 1506, which may include memory, processing circuitry, control circuitry, addressing circuitry, bus interconnection circuitry, or other circuitry or electronic devices that may be combined on a module with a memory device, such as the memory device 1504. Additionally, the memory module 1500 includes multiple electrical connections 1508, which may be used to connect the memory module 1500 to other electronic components, including other modules.

As shown in FIG. 15B, in some embodiments, these modules may be stackable, to form a stack 1550. For example, a stackable memory module 1552 may contain one or more memory devices 1556, arranged on a stackable substrate 1554. The memory device 1556 contains memory cells that employ memory elements in accordance with an embodiment of the invention. The stackable memory module 1552 may also include one or more electronic devices 1558, which may include memory, processing circuitry, control circuitry, addressing circuitry, bus interconnection circuitry, or other circuitry or electronic devices that may be combined on a module with a memory device, such as the memory device 1556. Electrical connections 1560 are used to connect the stackable memory module 1552 with other modules in the stack 1550, or with other electronic devices. Other modules in the stack 1550 may include additional stackable memory modules, similar to the stackable memory module 1552 described above, or other types of stackable modules, such as stackable processing modules, control modules, communication modules, or other modules containing electronic components.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit having a cell, the cell comprising:
a first source/drain region;
a second source/drain region;
an active region between the first source/drain region and the second source/drain region;
a gate insulating region disposed above the active region;
a gate region disposed above the gate insulating region; and
at least one metal structure below the first source/drain region.

2. The integrated circuit of claim 1, wherein the at least one metal structure is electrically coupled to the first source/drain region.

3. The integrated circuit of claim 1, wherein the at least one metal structure comprises a diffusion barrier material with respect to the first source/drain region.

4. The integrated circuit of claim 1, further comprising a carrier, wherein the active region is formed in the carrier.

5. The integrated circuit of claim 4, wherein the at least one metal structure comprises a diffusion barrier material with respect to the carrier.

6. The integrated circuit of claim 4, wherein the carrier comprises silicon.

7. The integrated circuit of claim 1, wherein the at least one metal structure is made of a material selected from the group of materials consisting of:
titanium nitride;
titanium aluminum nitride;
tantalum silicon nitride;
tungsten;
tungsten salicide;
cobalt salicide; and
titanium salicide.

8. The integrated circuit of claim 1, further comprising a diffusion barrier between the metal structure and the first source/drain region.

9. The integrated circuit of claim 8, wherein the diffusion barrier between the metal structure and the first source/drain region comprises an electrically conductive material.

10. The integrated circuit of claim 4, further comprising a diffusion barrier between the metal structure and the carrier.

11. The integrated circuit of claim 1, wherein the first source/drain region and the second source/drain region are formed in a diffusion source material.

12. The integrated circuit of claim 11, wherein the diffusion source material comprises electrically conductive material.

13. The integrated circuit of claim 11, wherein the diffusion source material comprises a material selected from the group of materials consisting of:
amorphous silicon;
poly-silicon;
carbon;
germanium; and
salicide.

14. The integrated circuit of claim 1, wherein the cell comprises a memory cell.

15. The integrated circuit of claim 14, wherein the memory cell comprises a charge storage memory cell.

16. The integrated circuit of claim 15, wherein the charge storage memory cell comprises a floating gate memory cell or a charge trapping memory cell.

17. A cell, comprising:
a first source/drain region;
a second source/drain region;
an active region between the first source/drain region and the second source/drain region;
a gate insulating region disposed above the active region;
a gate region disposed above the gate insulating region; and
at least one metal structure below the first source/drain region.

18. The cell of claim 17, further comprising a charge storage region disposed above the gate insulating region, wherein the gate region is disposed above the charge storage region.

19. The cell of claim 18, wherein the charge storage region comprises a floating gate region or a charge trapping region.

20. The cell of claim 17, wherein the at least one metal structure is electrically coupled to the first source/drain region.

21. The cell of claim 17, wherein the at least one metal structure is made of a diffusion barrier material with respect to the first source/drain region or the second source/drain region.

22. The cell of claim 17, further comprising a diffusion barrier between the metal structure and the first source/drain region.

23. A cell arrangement, comprising:
a first cell, the first cell comprising:
a first source/drain region;
a second source/drain region;
an active region between the first source/drain region and the second source/drain region;
a gate insulating region disposed above the active region;
a gate region disposed above the gate insulating region;
a second cell adjacent to the first cell, the second cell comprising:
a first source/drain region;
a second source/drain region;
an active region between the first source/drain region and the second source/drain region;
a gate insulating region disposed above the active region;
a gate region disposed above the gate insulating region; and
at least one metal structure below the second source/drain region of the first cell and the first source/drain region of the second cell.

24. The cell arrangement of claim 23, wherein the second source/drain region of the first cell and the first source/drain region of the second cell are formed as a common source/drain region.

25. The cell arrangement of claim 24, wherein the at least one metal structure is electrically coupled to the second source/drain region of the first cell and the first source/drain region of the second cell.

26. The cell arrangement of claim 24, wherein the at least one metal structure comprises a diffusion barrier material with respect to the second source/drain region of the first cell and the first source/drain region of the second cell.

27. The cell arrangement of claim 24, further comprising a diffusion barrier between the metal structure and the second source/drain region of the first cell and the first source/drain region of the second cell.

28. The cell arrangement of claim 24, wherein the first cell and the second cell comprise memory cells.

29. The cell arrangement of claim 28, wherein the memory cells comprise charge storage memory cells.

30. The cell arrangement of claim 29, wherein the charge storage memory cells comprise floating gate memory cells or charge trapping memory cells.

31. A method for manufacturing an integrated circuit, the method comprising:
forming an active region;
forming a gate insulating region above the active region;
forming a gate region above the gate insulating region;
forming at least one trench adjacent to the active region;
forming at least one metal structure in the trench; and
forming a source/drain region above the at least one metal structure.

32. The method of claim 31,
wherein forming the at least one trench next to the active region comprises:
forming a first trench on one side next to the active region; and
forming a second trench on an opposite side next to the active region;
wherein forming the at least one metal structure in the trench comprises:
forming a first metal structure in the first trench; and
forming a second metal structure in the second trench;
wherein forming the source/drain region above the at least one metal structure comprises:
forming a first source/drain region above the first metal structure; and
forming a second source/drain region above the second metal structure.

33. The method of claim 31, wherein the at least one metal structure is electrically coupled to the source/drain region.

34. The method of claim 31, wherein the at least one metal structure comprises a diffusion barrier material with respect to the source/drain region.

35. The method of claim 31, wherein the active region is formed in a carrier.

36. The method of claim 35, wherein the at least one metal structure comprises a diffusion barrier material with respect to the carrier.

37. The method of claim 35, wherein the carrier comprises silicon.

38. The method of claim 31, wherein the at least one metal structure comprises a material selected from the group of materials consisting of:
titanium nitride;
titanium aluminum nitride;
tantalum silicon nitride;
tungsten;
tungsten salicide;
cobalt salicide; and
titanium salicide.

39. The method of claim 31, further comprising:
forming a diffusion barrier above the at least one metal structure; and
forming the source/drain region above the diffusion barrier.

40. The method of claim 39, wherein the diffusion barrier between the at least one metal structure and the source/drain region and comprises an electrically conductive material.

41. The method of claim 31, wherein forming the source/drain region comprises:
forming diffusion source material above the at least one metal structure; and
forming the source/drain region in the diffusion source material.

42. The method of claim 41, wherein the diffusion source material comprises an electrically conductive material.

43. The method of claim 41, wherein the diffusion source material comprises a material selected from the group of materials consisting of:
amorphous silicon;
poly-silicon;
carbon;
germanium; and
salicide.

44. The method of claim 31, wherein the cell comprises a memory cell.

45. The method of claim 44, wherein the memory cell comprises a charge storage memory cell.

46. The method of claim 45, wherein the charge storage memory cell comprises a floating gate memory cell or a charge trapping memory cell.

47. A method for manufacturing a cell arrangement, the method comprising:
forming a partial first cell, the partial first cell comprising:
an active region;
a gate insulating region disposed above the active region;
a gate region disposed above the gate insulating region;
forming a partial second cell adjacent to the partial first cell, the partial second cell comprising:
an active region;
a gate insulating region disposed above the active region;
a gate region disposed above the gate insulating region;
forming at least one trench between the active region of the partial first cell and the active region of the partial second cell;
forming at least one metal structure in the trench;
forming a source/drain region of the partial first cell and the partial second cell above the at least one metal structure.

48. An integrated circuit having a cell means, the cell means comprising:
first source/drain means;
second source/drain means;
active region means between the first source/drain means and the second source/drain means;
gate insulating means disposed above the active region means;
gate means disposed above the gate insulating means; and
at least one metal structure means below the first source/drain means or the second source/drain means.

49. A cell, comprising:
a first source/drain region;
a second source/drain region;
an active region between the first source/drain region and the second source/drain region;
a gate insulating region disposed above the active region;
a gate region disposed above the gate insulating region; and
at least one metal structure, wherein the at least one metal structure is made of a material that acts as a diffusion barrier with regard to the first source/drain region or the second source/drain region.

50. A cell, comprising:
a first source/drain region;
a second source/drain region;
an active region between the first source/drain region and the second source/drain region;
a gate insulating region disposed above the active region;
a gate region disposed above the gate insulating region;
at least one metal structure; and
a diffusion barrier between the at least one metal structure and the first source/drain region or between the at least one metal structure and the second source/drain region.

51. A memory module, comprising:
a multiplicity of integrated circuits, wherein at least one integrated circuit of the multiplicity of integrated circuits comprises a cell, the cell comprising:
a first source/drain region;
a second source/drain region;
an active region between the first source/drain region and the second source/drain region;
a gate insulating region disposed above the active region;
a gate region disposed above the gate insulating region; and
at least one metal structure below the first source/drain region.

52. The memory module of claim 51, wherein the integrated circuits are stacked above one another.
